(19) United States
(12) Patent Application Publication
(10) Pub. No.: US 2018/0033642 A1
(43) Pub. Date: Feb. 1, 2018

(54) THIN FILM TRANSISTOR, ARRAY SUBSTRATE, AND DISPLAY APPARATUS, AND THEIR FABRICATION METHODS

(71) Applicant: BOE TECHNOLOGY GROUP CO., LTD, Beijing (CN)

(72) Inventors: Xiaoyong LU, Beijing (CN); Dong LI, Beijing (CN); Xiaolong LI, Beijing (CN); Chunping LONG, Beijing (CN)

(21) Appl. No.: 15/325,117

(22) PCT Filed: Dec. 18, 2015
(86) PCT No.: PCT/CN2015/097883

§ 371 Date: Jan. 10, 2017

(51) Int. Cl. H01L 21/3205; H01L 29/45; C23C 14/00; C23C 14/14; C23C 14/34; C23C 14/06; H01L 21/768; H01L 27/12

(52) U.S. Cl. CPC H01L 21/32051; H01L 21/76895; H01L 29/458; H01L 27/1259; C23C 14/14; C23C 14/34; C23C 14/0641; C23C 14/0073

(57) ABSTRACT

The present disclosure provides a thin film transistor, a thin film transistor array substrate, and a display apparatus, and their fabrication methods. The thin film transistor is formed by forming a source and drain electrode structure. To form the source and drain electrode structure, at least one metal film is formed using a target of a metal element in a sputtering chamber. A gas is introduced in the sputtering chamber to in-situ react with the metal element to form an anti-reflection layer over the at least one metal film.

### TECHNICAL FIELD

The present disclosure generally relates to the field of display technologies and, more particularly, relates to a thin film transistor (TFT), a thin film transistor array substrate, and a display apparatus, and their fabrication methods.

### BACKGROUND

In recent years, thin-film-transistor (TFT) array substrate has been widely used in flat panel display field, especially in the organic light-emitting diode (OLED) display field. Typically, a TFT array substrate may include a low temperature poly silicon (LTPS) TFT having a source and drain (SD) metal layer.

However, conventional SD metal layer often includes a metal with a high reflectivity to an incident light. Such high reflectivity may disturb subsequent exposure process(es).

Accordingly, it is desirable to provide a thin film transistor (TFT), a thin film transistor array substrate, and a display apparatus, and their fabrication methods to at least partially alleviate one or more problems set forth above and to solve other problems in the art.

### BRIEF SUMMARY

An aspect of the present disclosure provides a method for forming a thin film transistor including forming a source and drain electrode structure. To form the source and drain electrode structure, at least one metal film is formed using a target of a metal element in a sputtering chamber, and a gas is introduced in the sputtering chamber to in-situ react with the metal element to form an anti-reflection layer over the at least one metal film.

Optionally, the anti-reflection layer has a reflectivity lower than any of the at least one metal film.

Optionally, the method further includes controlling a concentration of the reactive gas introduced in the sputtering chamber to control a reflectivity of the anti-reflection layer.

Optionally, the anti-reflection layer has a thickness ranging from about 10 nm to about 100 nm.

Optionally, the gas contains nitrogen, and the anti-reflection layer is a nitride film of the metal element.

Optionally, the step of forming at least one metal film includes forming a first metal film containing a first metal element, and forming a second metal film over the first metal film using the target of the metal element in the sputtering chamber.

Optionally, while the second metal film is being formed by a sputtering process in the sputtering chamber, the reactive gas is introduced to the sputtering chamber to form the anti-reflection layer over the second metal film.

Optionally, the first metal element is aluminum.

Optionally, the source and drain electrode structure further includes a third metal film under the first metal film, the third metal film containing a third metal element.

Optionally, the metal element and the third metal element are a same.

Optionally, the metal element includes titanium.

Optionally, the anti-reflection layer includes a titanium nitride (TiNx) film.

Another aspect of the present disclosure provides a method for forming a thin film transistor array substrate according to the disclosed method for forming the thin film transistor.

Optionally, the method further includes forming a pixel electrode layer over the source and drain electrode structure and electrically contacting the source and drain electrode structure.

Another aspect of the present disclosure provides a thin film transistor formed by the disclosed method.

Another aspect of the present disclosure provides a thin film transistor array substrate formed by the disclosed method.

Another aspect of the present disclosure provides a display apparatus, including the disclosed thin film transistor array substrate.

Other aspects of the present disclosure can be understood by those skilled in the art in light of the description, the claims, and the drawings of the present disclosure.

### BRIEF DESCRIPTION OF THE DRAWINGS

Various objects, features, and advantages of the disclosed subject matter can be more fully appreciated with reference to the following detailed description of the disclosed subject matter when considered in connection with the following drawings, in which like reference numerals identify like elements. It should be noted that the following drawings are merely examples for illustrative purposes according to various disclosed embodiments and are not intended to limit the scope of the present disclosure.

FIG. 1 is a schematic cross-sectional structure diagram of an exemplary TFT in accordance with various disclosed embodiments of present disclosure; and

FIG. 2 shows an exemplary method for fabricating an exemplary TFT in accordance with various disclosed embodiments of present disclosure.

### DETAILED DESCRIPTION

For those skilled in the art to better understand the technical solution of the disclosed subject matter, reference will now be made in detail to exemplary embodiments of the disclosed subject matter, which are illustrated in the accompanying drawings. Wherever possible, the same reference numbers will be used throughout the drawings to refer to the same or like parts.

In accordance with various embodiments, the present disclosure provides a thin film transistor (TFT), a thin film transistor array substrate, and a display apparatus, and their fabrication methods.

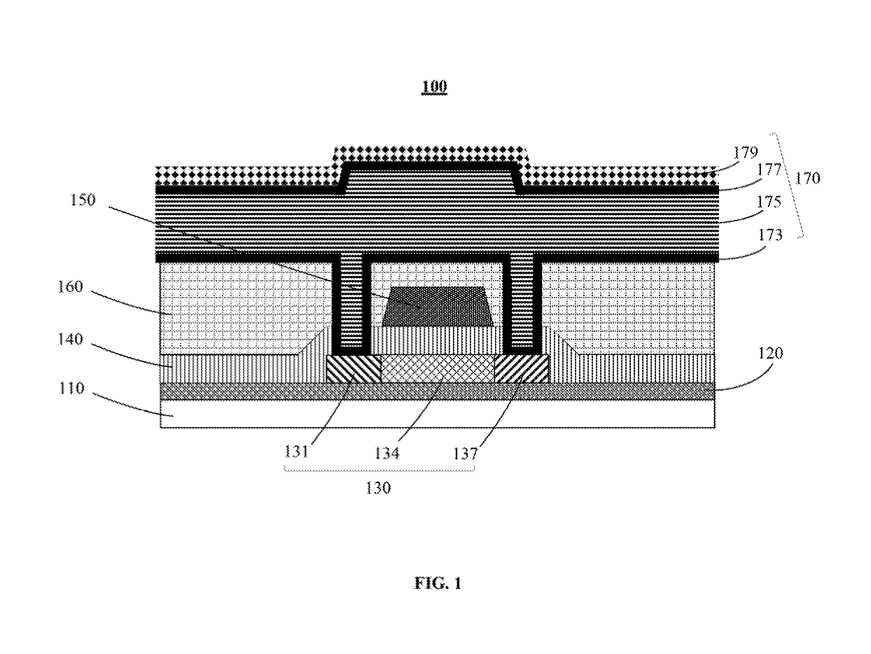

Turning to FIG. 1, a schematic cross-sectional structure diagram of an exemplary TFT 100 is shown in accordance with various disclosed embodiments of present disclosure. The exemplary TFT 100 may be used in a TFT array substrate including a bottom gate type TFT or a top gate type TFT. FIG. 1 shows a top gate type TFT as an example to illustrate the detailed structure of the disclosed subject matter and is not intended to limit the scope of the present disclosure.

As illustrated, TFT 100 can include: base substrate 110, first insulating layer 120, active layer 130, second insulating layer 140, gate electrode 150, passivation layer 160, and source and drain electrode structure 170. Certain layers and components may be omitted and other layers and components may be included.

In some embodiments, base substrate 110 can be any suitable substrate. For example, base substrate 110 can be an optically transparent substrate made of glass, quartz, or plastic. As another example, base substrate 110 can be a flexible substrate made of a polymer, such as polyethylene naphthalate (PEN), polyethylene terephthalate (PET), or polyimides (PI). As another example, base substrate 110 can be a metal foil substrate made of a metal or an alloy. In some embodiments, base substrate 110 can include one or more of a buffer layer and an aqueous oxygen barrier layer.

In some embodiments, first insulating layer 120 is located on base substrate 110. First insulating layer 120 can be made of an insulating material such as, for example, silicon nitride (SiN₁), silicon oxide (SiOₓ), silicon oxynitride (SiOₓN_{y}), aluminum oxide (AlOₓ), yttrium oxide (Y₂O₃), hafnium oxide (HfOₓ), zirconium oxide (ZrOₓ), aluminum nitride (AlN), aluminum oxynitride (AlNO), titanium oxide (TiOₓ), barium titanate (BaTiO₃), lead titanate (PbTiO₃), or a combination thereof. In some embodiments, first insulating layer 120 can have any suitable thickness, such as a thickness between 50 nm and 500 nm.

In some embodiments, active layer 130 is located on the first insulating layer 120. Active layer 130 can be an inorganic metal oxide semiconductor thin film. For example, active layer 130 can be made of an oxynitride material such as ZnON.

In some embodiments, active layer 130 can include a source region 131, a drain region 137, and a channel region 134 located between source region 131 and drain region 137, as shown in FIG. 1. In some embodiments, source region 131 and drain region 137 can be heavily-doped regions, and channel region 134 can be a non-doped region.

Optionally, a lightly-doped drain (LDD) structure can be used to increase the length of TFT channel. For example, the LDD region can be formed between channel region 134 and drain region 137. Likewise, a lightly-doped region can be formed between channel region 134 and source region 131.

In some embodiments, second insulating layer 140 is located on and encases active layer 130. Second insulating layer 140 can be made of an insulating material such as, for example, silicon nitride (SiNₓ), silicon oxide (SiOₓ), silicon oxynitride (SiOₓN_{y}), aluminum oxide (AlOₓ), yttrium oxide (Y₂O₃), hafnium oxide (HfOₓ), zirconium oxide (ZrOₓ), aluminum nitride (AlN), aluminum oxynitride (AlNO), titanium oxide (TiOₓ), barium titanate (BaTiO₃), lead titanate (PbTiO₃), or a combination thereof. In some embodiments, second insulating layer 140 can have any suitable thickness, such as a thickness between 50 nm and 500 nm.

In some embodiments, gate electrode 150 can be located on second insulating layer 140. In some embodiments, gate electrode 150 can include a gate buffer layer, a gate electrode layer, and a gate capping layer (not illustrated). For example, the gate electrode layer can be sandwiched between the gate buffer layer and the gate capping layer. The gate capping layer can be on top of the gate electrode layer. The gate buffer layer may have a thickness of about 100 nm or less, for example, about 20 nm to about 100 nm.

Each of the gate buffer layer, the gate electrode layer, and the gate capping layer can be made of same or different electrically conductive materials. Non-limiting examples of the electrically conductive materials may include: one or more of metal material and transparent conductive material. The metal material may include aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), cobalt (Co), manganese (Mn), and any mixtures or alloys thereof. The transparent conductive material may include, for example, an indium tin oxide (ITO), an indium zinc oxide (IZO), and an aluminum doped zinc oxide (AZO).

The combination of the gate buffer layer, the gate electrode layer, and the gate capping layer can provide layers with different physical properties. For example, the gate electrode layer may be made of metal copper, the gate buffer layer may facilitate to provide adhesion between the gate electrode layer and the underlying layer such as base substrate 110. As another example, the gate capping layer may be used as a diffusion barrier layer to prevent diffusion of copper ions from the gate electrode layer. As another example, the gate capping layer may be a carbon nanotube (CNT) monolayer to provide a superior transporting channel.

In some embodiments, the gate buffer layer and the gate capping layer can be optional and can be omitted.

Passivation layer 160 is located on the second isolating layer 140 and gate electrode 150. Passivation layer 160 encases gate electrode 150. In some embodiments, passivation layer 160 can include one or more insulating films. For example, passivation layer 160 can be SiO₂ film, Si₃N₄ film, Al₂O₃ film, Y₂O₃ film, polyimide film, photoresist film, benzocyclobutene film, or polymethyl methacrylate (PMMA) film. As another example, passivation layer 160 can be multiple layers of insulating films that include one or more suitable insulating materials. In some embodiments, the thickness of passivation layer 160 is between 100 nm and 2000 nm.

Source and drain (SD) electrode structure 170, also referred to as SD electrode structure 170, is located on passivation layer 160. In some embodiments, SD electrode structure 170 can pass through passivation layer 160 and second insulating layer 140 through via holes (not illustrated) to physically and electrically connect the source region 131 and drain region 137, respectively, as illustrated in FIG. 1.

It should be noted that, although not shown in FIG. 1, SD electrode structure 170 can be further patterned and then etched by any suitable processes to form separate source electrode structure and drain electrode structure.

As disclosed herein, SD electrode structure 170 can include at least one metal film and an anti-reflection layer 179 formed over the at least one metal film. The at least one metal film may include, for example, multiple layers of conductive thin films.

For example, the at least one metal film in SD electrode structure 170 can include a first metal film 175, a second metal film 177, and a third metal film 173, as illustrated in FIG. 1. The second metal film 177 may be formed on the first metal film 175, and the first metal film 175 may be formed on the third metal film 173.

First metal film 175 can be a first wiring layer, for example, made of a first metal element such as aluminum (Al), copper (Cu), gold (Au), silver (Ag), or other suitable metal material. In some embodiments, third metal film 173 and second metal film 177 can be made of a second metal element, such as titanium (Ti) or molybdenum (Mo). For example, the at least one metal film in SD electrode structure 170 can have a Ti—Al—Ti metal structure, or a Mo—Al—Mo metal structure. In other words, the at least one metal film can have three layers in order.

Each of first metal film 175, second metal film 177, and third metal film 173, can have any suitable thicknesses. For example, first metal film 175 can have a thickness in a range between 100 nm to 800 am, while each of third metal film 173 and second metal film 177 can have thicknesses between 10 nm to 100 nm.

In some embodiments, the at least one metal film including the first, second, and third metal films in SD electrode structure 170 have an undesirably high reflectivity. For example, for an incident light at a wavelength of about 400 nm, the reflectivity of Al film having a thickness of about 400 nm can be about 85%, and the reflectivity of Ti film having a thickness of about 400 nm can be about 45%. In some cases, the thickness of second metal film 177 is much less than that of the first metal film 175, and the resultant reflectivity of the at least one metal film of the SD electrode structure 170 may depend more on the first metal film 175.

The high reflectivity of the at least one metal film may be adversely affect subsequent photolithographic processes. For example, abnormal graphics of the exposure patterns may be caused by the high reflectivity. This problem can be more serious for high-resolution LTPS TFT array substrates.

As such, in addition to the at least one metal film, e.g., including first metal film 175, second metal film 177, and third metal film 173, SD electrode structure 170 may further include anti-reflection layer 179 formed on the at least one metal film.

In some embodiments, the at least one metal film of SD electrode structure 170, including third metal film 173, first metal film 175, and second metal film 177, can be formed by one or more suitable deposition processes including, for example, a physical vapor deposition (PVD) process, such as evaporation, sputtering, cathodic arc deposition, or electron beam heating. As another example, the at least one metal film of SD electrode structure 170 can be formed by electrochemical deposition or chemical vapor deposition (CVD), such as a low temperature plasma-enhanced chemical vapor deposition (PECVD) process. As another example, the at least one metal film of SD electrode structure 170 can be formed by molecular beam epitaxy, atomic layer deposition, or any other suitable method.

In some embodiments, anti-reflection layer 179 can be a compound containing the second metal element in the second metal film 177, such as a nitride of the second metal element. For example, when the second metal element is Ti, the compound can be titanium nitride (TiNx), titanium carbon nitride (TiCN), titanium aluminum nitride (TiAlN), or titanium aluminum carbon nitride (TiAlCN). In one embodiment, anti-reflection layer 179 can be a TiNx film.

In other embodiments, the anti-reflection layer 179 can be a compound containing a metal element in first metal film 175 or third metal film 173.

Anti-reflection layer 179 can have any suitable thickness. For example, anti-reflection layer 179 can be a TiNx film with a thickness between 10 nm to 100 nm.

Anti-reflection layer 179 can have a low reflectivity, for example, at least less than each of the first, second, and third metal films. For example, for an incident light at a wavelength of about 450 nm, the reflectivity of anti-reflection layer 179 made of a TiNx film having a thickness of about 30 nm can be about 20%.

In some embodiments, second metal film 177 and anti-reflection layer 179 can be formed in a same reaction chamber. For example, sputtering deposition processes may be performed in a same sputtering chamber using a same metal target, e.g., of the second metal element such as a Ti metal target.

In one embodiment, the second metal film 177 can be formed by a sputtering deposition process over the first metal film 175 placed in the sputtering chamber. An inert gas may be provided in the sputtering chamber. For example, the inert gas may be introduced into the sputtering chamber when depositing the metal film, such as a Ti metal film. The inert gas can contain one or more gases that do not chemically react with the sputtered ions and atoms ejected from the target metal. The inert gas may include, for example, helium, neon, argon, or any other suitable gas, or a compound gas of any suitable combinations thereof.

In other embodiments, the inert gas may not be provided in the sputtering chamber.

After the second metal film 177 is formed, or while the second metal film 177 is being deposited to a certain point, a gas, such as a reactive gas, can be introduced in the same sputtering chamber to in-situ react with the target of the second metal element to form the anti-reflection layer 179 over the second metal film 177.

The reactive gas can be introduced into the sputtering chamber along with, e.g., inert gas(es). In other words, a gas mixture including the reactive gas having an appropriate amount, such as appropriate percentage, thereof can be introduced and then chemically react with the sputtered ions and atoms ejected from the target material. For example, the reactive gas can be one or more of oxygen, nitrogen, and carbon-containing gas. Therefore, during the in-situ reactive sputtering stage in the same sputtering chamber, an oxide, nitride, or carbon nitride thin film can be formed on the second metal film 177 that has been previously formed in a non-reactive sputtering stage.

In a particular example, SD electrode structure 170 may include a Ti—Al—Ti metal structure formed by the at least one metal film, and the anti-reflection layer 179 thereon. The anti-reflection layer 179 may be a titanium nitride (TiNx) formed on the Ti—Al—Ti metal structure. In one embodiment, second metal film 177 and anti-reflection layer 179 can be formed by a single sputtering deposition process in a same sputtering chamber using a single Ti metal target. By introducing a reactive gas during the sputtering deposition process for forming the second metal layer 177, anti-reflection layer 179 may be formed on the second metal layer 177 in the single sputtering chamber.

In such particular example, when forming the second metal layer 177, inert gas(es) introduced in the sputtering chamber can contain only an inert gas such as argon during the non-reactive sputtering stage. When forming the anti-reflection layer 179, reactive gas such as nitrogen may be introduced into the single sputtering chamber during the reactive sputtering stage. Therefore, a Ti metal film can be formed as second metal film 177 in the non-reactive sputtering stage, and a TiNx film can be formed as anti-reflection layer 179 in the reactive sputtering stage.

In some embodiments, the concentration of the reactive gas in the sputtering chamber can be adjusted gradually over time. For example, the concentration of the reactive gas such as nitrogen in the gas mixture can be gradually increased over time. In this case, there may not have a clear boundary between the non-reactive sputtering stage and the reactive sputtering stage, and may not have a clear boundary between second metal film 177 and anti-reflection layer 179. For example, a TiTiNx structure can be formed by the single sputtering deposition process, the bottom side of the TiTiNx structure can have a high percentage of Ti metal and low percentage of TiNx, while the top side of the TiTiNx structure can have a high percentage of TiNx and low percentage of Ti metal.

In some cases, there may have a clear boundary between the non-reactive sputtering stage and the reactive sputtering stage, and may have a clear boundary between second metal film 177 and anti-reflection layer 179.

In some embodiments, during the sputtering deposition process that forms anti-reflection layer 179, the concentration of the reactive gas can be adjusted according to different technical needs. For example, the concentration of nitrogen within the gas mixture flowing into the sputtering chamber can be adjusted to provide anti-reflection layer 179 with different reflectivity. In a particular example, the concentration of nitrogen or any other reactive gas within the gas mixture can be increased in order to obtain a lower reflectivity film. In another particular example, a mid-range concentration of nitrogen within the gas mixture can correspond to a film including both Ti and TiNx, which means that the reflectivity of the film is also in a mid-range.

It should be noted that, although not shown in FIG. 1, SD electrode structure 170 including anti-reflection layer 179 and the at least one metal film, e.g., including the first, second, and third metal film 175/177/173 can be further patterned and then etched by any suitable processes to separate source electrode structure from drain electrode structure.

It should also be noted that, any suitable layers can be further formed on anti-reflection layer 179, such as passivation (PVX) layer, planarization (PLN) layer, pixel electrode layer (PXL), pixel defining layer (PDL), etc., to form a TFT array substrate.

Accordingly, a TFT array substrate including the SD electrode structure 170 can be provided. The anti-reflection layer having a low reflectivity can cover the metal layers having a high reflectivity, and thereby to effectively improve the pattern formation in the subsequent photolithographic processes, and provide technical support for high-resolution LTPS substrate technology. Moreover, the anti-reflection layer can be formed in a single deposition chamber and a single deposition process that form a second metal film, by merely introducing and adjusting the reactive gas in the deposition process without using extra deposition chamber or additional process.

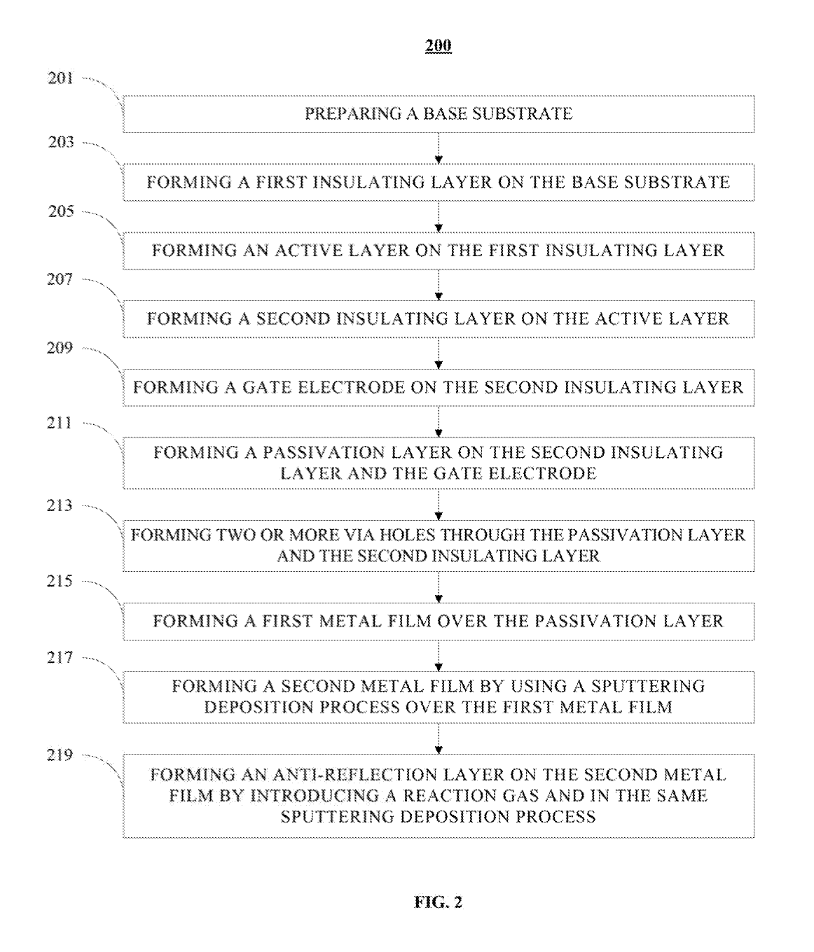

Turning to FIG. 2, an exemplary method 200 for fabricating the disclosed TFT array substrate is shown in accordance with some embodiments of the disclosed subject matter.

As illustrated, method 200 can start by preparing a base substrate at 201. In some embodiments, the base substrate can be any suitable substrate. For example, the base substrate can be an optically transparent substrate made of glass, quartz, or plastic. As another example, the base substrate can be a flexible substrate made of a polymer, such as polyethylene naphthalate (PEN), polyethylene terephthalate (PET), or polyimides (PI). As yet another example, the base substrate can be a metal foil substrate made of a metal or an alloy. In some embodiments, the base substrate can include one or more of a buffer layer and an aqueous oxygen barrier layer.

At 203, a first insulating layer can be formed on the base substrate.

Next, at 205, an active layer can be formed on the first insulating layer. The active layer can be an inorganic metal oxide semiconductor thin film made of an oxynitride material such as ZnON.

In some embodiments, the active layer can include a channel region located between the source region and the drain region. In some embodiments, the source region and the drain region are heavily-doped regions, and the channel region is a non-doped region or a lightly-doped region.

At 207, a second insulating layer can be formed on the first insulating layer and the active layer. The second insulating layer is formed to encase the active layer.

The first insulating layer and the second insulating layer can be made of an insulating material such as, for example, silicon nitride (SiNₓ), silicon oxide (SiOₓ), silicon oxynitride (SiOₓN_{y}), aluminum oxide (AlOₓ), yttrium oxide (Y₂O₃), hafnium oxide (HfOₓ), zirconium oxide (ZrOₓ), aluminum nitride (AlN), aluminum oxynitride (AlNO), titanium oxide (TiOₓ), barium titanate (BaTiO₃), lead titanate (PbTiO₃), or a combination thereof. In some embodiments, the first insulating layer and the second insulating layer can have any suitable thicknesses, such as a thickness between 50 nm and 500 nm.

At 209, a gate electrode can be formed on the second insulating layer and located corresponding to the channel region of the active layer.

In some embodiments, the gate electrode may include a gate buffer layer, a gate electrode layer, and a gate capping layer. The gate electrode layer can be sandwiched between the gate buffer layer and the gate capping layer. The gate capping layer can be on top of the gate electrode layer. The gate buffer layer may have a thickness of about 100 nm or less, for example, about 20 nm to about 100 nm.

Each of the gate buffer layer, the gate electrode layer, and the gate capping layer can be made of same or different electrically conductive materials. Non-limiting examples of the electrically conductive materials may include: one or more of metal material and transparent conductive material. The metal material may include aluminum (Al), copper (Cu), molybdenum (Mo), titanium (Ti), nickel (Ni), tungsten (W), gold (Au), palladium (Pd), platinum (Pt), chromium (Cr), neodymium (Nd), zinc (Zn), cobalt (Co), manganese (Mn), and any mixtures or alloys thereof. The transparent conductive material may include, for example, an indium tin oxide (ITO), an indium zinc oxide (IZO), and an aluminum doped zinc oxide (AZO).

At 211, a passivation layer can be formed on the second isolating layer and the gate electrode. The passivation layer is formed to encase the gate electrode. In some embodiments, the passivation layer can include one or more insulating films. For example, the passivation layer can be SiO₂ film, SiN₄ film, Al₂O₃ film, Y₂O₃ film, polyimide film, photoresist film, benzocyclobutene film, or polymethyl methacrylate (PMMA) film. As another example, the passivation layer can be multiple layers of insulating films that comprise one or more suitable insulating materials. In some embodiments, the thickness of the passivation layer is between 100 nm and 2000 nm.

At 213, two or more via holes can be formed through the passivation layer and the second insulating layer. The two or more via holes can be formed by any suitable patterning and etching processes, and can expose the source region and the drain region, respectively.

At 215, a first metal film of the one or more metal films can be formed over the passivation layer.

The one or more metal films can pass through the passivation layer and the second insulating layer by the two or more via holes formed at 213, and directly contact with the source region and the drain region.

In some embodiments, the one or more metal films can be formed by one or more suitable deposition processes. For example, each of the metal films can be formed by using a physical vapor deposition (PVD) process, such as evaporation, sputtering, cathodic arc deposition, or electron beam heating. As another example, each of the metal films can be formed by electrochemical deposition, or chemical vapor deposition (CVD) such as a low temperature plasma-enhanced chemical vapor deposition (PECVD) process. As yet another example, each of the metal films can be formed by molecular beam epitaxy, atomic layer deposition, or any other suitable method.

In some embodiments, the one or more metal films include a first metal film, a second metal film, and a third metal film. The first metal film is a first wiring layer, for example, made of a first metal such as aluminum (Al), copper (Cu), gold (Au), silver (Ag), or other suitable metal material. The third metal film is made of a second metal element, such as titanium (Ti) or molybdenum (Mo).

The one or more metal films can be formed having any suitable thicknesses. For example, the first metal film can have a thickness in a range between 100 nm to 800 nm, and the third metal film can have a thickness between 10 nm to 100 nm.

At 217, a second metal film can be formed by using a sputtering deposition process over the first metal film. For example, a second metal film of titanium (Ti) can be deposited by sputtering a Ti target in a sputtering chamber. The sputtering chamber can have any suitable temperature and have any suitable sputtering gas environment. For example, a flow of inert gas such as argon can be introduced to the sputtering chamber during the sputtering deposition process. Since there is no chemical reaction between the flow of argon and the sputtered Ti ions and Ti atoms ejected from the target, a Ti film can be formed on the substrate.

At 219, by introducing a reactive gas, an anti-reflection layer can be formed in a same sputtering deposition process and same sputtering chamber that the second metal film is formed.

The anti-reflection layer can be formed on the second metal film. In some embodiments, the anti-reflection layer can be a compound of the second metal element of second metal film, such as a Ti nitride (TiNx) film. The anti-reflection layer can have any suitable thickness, for example, in a range between 10 nm to 100 nm.

During the same sputtering deposition process that forms the second metal film, the anti-reflection layer is formed by adjusting gas component in the sputtering chamber. For example, after the second metal film of titanium (Ti) has been deposited by sputtering a Ti target in a sputtering chamber, the gas flowing into the sputtering chamber can be adjusted to contain a reactive gas, such as nitrogen. As another example, after the second metal film of titanium (Ti) has been deposited by sputtering a Ti target in a sputtering chamber, a concentration of reactive gas such as nitrogen in a gas mixture flowing into the sputtering chamber can be increased. Since the nitrogen can chemically react with the sputtering Ti ions and Ti atoms ejected from the target, a TiNx film can be formed on the second metal film.

In some embodiments, during the sputtering deposition process that forms the second metal film at 217 and the anti-reflection layer at 219, the concentration of the reactive gas component in the gas mixture can be adjusted gradually over time. For example, the concentration of nitrogen within the gas mixture can be gradually increased over time. In this case, there may or may not be a clear boundary between the second metal film and the anti-reflection layer. For example, a TiTiNx structure can be formed by the sputtering deposition process, wherein the bottom side of the TiTiNx structure can have a high percentage of Ti metal and low percentage of TiNx, while the top side of the TiTiNx structure can have a high percentage of TiNx and low percentage of Ti metal.

In some embodiments, during the sputtering deposition process that forms the anti-reflection layer at 219, the concentration of the reactive gas component can be adjusted according to different technical needs. For example, the concentration of nitrogen within the gas mixture flowing into the sputtering chamber can be adjusted to provide anti-reflection layer 179 with different reflectivity. In a particular example, the concentration of nitrogen within the gas mixture can be increased in order to obtain a lower reflectivity film. In another particular example, a mid-range concentration of nitrogen within the gas mixture can correspond to a film including both Ti and TiNx, which means that the reflectivity of the film is also in a mid-range.

It should be noted that, in some embodiments, the at least one metal film including the first, second and third metal films in SD structure have an undesirably high reflectivity. For example, for an incident light at a wavelength of about 400 nm, the reflectivity of Al film having a thickness of about 400 nm can be about 85%, and the reflectivity of Ti film having a thickness of about 30 nm can be about 45%. For an anti-reflection TiNx film having a thickness of about 30 nm, the reflectivity is about 20% for an incident light at a wavelength of about 450 nm.

It also should be noted that, although not shown in FIG. 2, one or more processes can be further performed after forming the anti-reflection layer. For example, the SD structure can be further patterned and then etched by any suitable following procedures to form source electrode structure and drain electrode structure. As another example, any suitable layers can be further formed on the anti-reflection layer, such as passivation (PVX) layer, planarization (PLN) layer, pixel electrode layer (PXL), pixel defining layer (PDL), etc. to form a TFT substrate array.

It also should be noted that the above steps of the flow diagram of FIG. 2 can be executed or performed in any order or sequence not limited to the order and sequence shown and described in the figure. Also, some of the above steps of the flow diagram of FIG. 2 can be executed or performed substantially simultaneously where appropriate or in parallel to reduce latency and processing times. Furthermore, it should be noted that FIG. 2 is provided as an example only. At least some of the steps shown in the figure may be performed in a different order than represented, performed concurrently, or altogether omitted. Some additional steps not shown in the figure may be performed between any of the steps shown in the figure.

Accordingly, a method for fabricating the disclosed TFT and an array substrate thereof can be provided to include a SD electrode structure including at least one metal layer and an anti-reflection layer on the at least one metal layer. The anti-reflection layer having a low reflectivity can cover the at least one metal layer having a high reflectivity, and thereby effectively improving the patterns formation in the follow-up photolithographic processes, and provide technical support for high-resolution LTPS substrate technology. Moreover, the disclosed method can form the at least one metal film and the anti-reflection layer in a same deposition process by only adjusting gas introduced into the sputtering chamber. No extra deposition chamber or additional processes are needed.

Various embodiments further include a display apparatus. The display apparatus may include the disclosed array substrate including the TFT, for example, as shown in FIG. 1. The disclosed display apparatus may be used in a liquid crystal display (LCD) apparatus, an organic light emitting diode (OLED) display apparatus, an electronic paper, a mobile phone, a tablet computer, a television, a monitor, a laptop, a digital photo frame, a navigation system, and other products with display function.

The provision of the examples described herein (as well as clauses phrased as “such as,” “e.g.,” “including,” and the like) should not be interpreted as limiting the claimed subject matter to the specific examples; rather, the examples are intended to illustrate only some of many possible aspects.

Although the disclosed subject matter has been described and illustrated in the foregoing illustrative embodiments, it is understood that the present disclosure has been made only by way of example, and that numerous changes in the details of embodiment of the disclosed subject matter can be made without departing from the spirit and scope of the disclosed subject matter, which is only limited by the claims which follow. Features of the disclosed embodiments can be combined and rearranged in various ways. Without departing from the spirit and scope of the disclosed subject matter, modifications, equivalents, or improvements to the disclosed subject matter are understandable to those skilled in the art and are intended to be encompassed within the scope of the present disclosure.

1-17. (canceled)

18. A method for fabricating a thin film transistor, comprising:
forming a source and drain electrode structure, comprising:
forming at least one metal film using a target of a metal element in a sputtering chamber, and
introducing a gas in the sputtering chamber to in-situ react with the metal element to form an anti-reflection layer over the at least one metal film.

19. The method according to claim 18, wherein the anti-reflection layer has a reflectivity lower than any of the at least one metal film.

20. The method according to claim 18, further comprising:
controlling a concentration of the gas introduced in the sputtering chamber to control a reflectivity of the anti-reflection layer.

21. The method according to claim 18, wherein the anti-reflection layer has a thickness ranging from about 10 nm to about 100 nm.

22. The method according to claim 18, wherein:
the gas contains nitrogen, and
the anti-reflection layer is a nitride film of the metal element.

23. The method according to claim 18, wherein the step of forming at least one metal film comprises:
forming a first metal film containing a first metal element, and
forming a second metal film over the first metal film using the target of the metal element in the sputtering chamber.

24. The method according to claim 23, further comprising:
while the second metal film is being formed by a sputtering process in the sputtering chamber, introducing the gas to the sputtering chamber to form the anti-reflection layer over the second metal film.

25. The method according to claim 23, wherein the first metal element is aluminum.

26. The method according to claim 23, wherein:
the source and drain electrode structure further includes a third metal film under the first metal film, the third metal film containing a third metal element.

27. The method according to claim 26, wherein the metal element and the third metal element are a same.

28. The method according to claim 18, wherein the metal element includes titanium.

29. The method according to claim 18, wherein the anti-reflection layer includes a titanium nitride (TiNx) film.

30. A method for fabricating a thin film transistor array substrate, comprising the method for fabricating the thin film transistor of claim 18.

31. The method according to claim 30, further comprising:
forming a pixel electrode layer over the source and drain electrode structure and electrically contacting the source and drain electrode structure.

32. A thin film transistor formed by the method according to claim 18.

33. A thin film transistor array substrate formed by the method according to claim 30.

34. A display apparatus, comprising the thin film transistor array substrate according to claim 33.
